(19) United States
(12) Patent Application Publication
(10) Pub. No.: US 2008/0168946 A1
(43) Pub. Date: Jul. 17, 2008

(54) Liquid supplying unit and method, facility for treating substrates with the unit, and method for treating substrates

(75) Inventors: Tae-Young Nam, Seoul (KR); Tae-Ho Kim, Suwon-si (KR); Ho-Wang Kim, Seoul (KR); Sang-Gon Lee, Hwaseong-si (KR); Byung-Ho Ahn, Yongin-si (KR); Hyung-Koo Kim, Hwaseong-si (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 12/006,668

(22) Filed: Jan. 4, 2008

(30) Foreign Application Priority Data
Jan. 12, 2007 (KR) 10-2007-0003838

(51) Int. Cl. C23C 16/54

(52) U.S. Cl. 118/726

(57) ABSTRACT

In a liquid supplying unit liquid is supplied from a buffer vessel to an external unit by pressurizing the liquid present in the buffer vessel using gas supplied to the buffer vessel. A pressure measuring member is provided to measure the pressure inside the buffer vessel, and when the pressure inside the buffer vessel is equal to or greater than a preset reference pressure during refilling of the buffer vessel, gas is discharged from the buffer vessel through a vent line.

### CROSS-REFERENCE TO RELATED APPLICATIONS

This U.S. non-provisional patent application claims priority under 35 U.S.C. § 119 of Korean Patent Application No. 10-2007-0003838, filed on Jan. 12, 2007, the entire contents of which are hereby incorporated by reference.

### BACKGROUND OF THE INVENTION

Embodiments of the present invention disclosed herein relate to an apparatus and method for treating substrates, and more particularly, to an apparatus and method for supplying a chemical from a buffer vessel by pressurizing the buffer vessel with gas.

Generally, the manufacture of semiconductor devices involves a number of processes such as ion implantation, deposition, photolithograph, and etching. In a deposition process, a thin layer is deposited on a wafer. Particularly, when an insulating metal oxide layer having a dielectric constant greater than that of a silicon nitride layer is deposited on a substrate, a sputtering method can be used. However, when the sputtering method is used, it is difficult to form fine patterns, and many particles that are produced during the sputtering process, can damage the underlying substrate. Therefore, in a recent approach, the insulating metal oxide layer is formed by chemical vapor deposition (CVD) using an organic metal compound as a precursor of the insulation metal oxide layer.

In an apparatus for depositing an organic metal layer by CVD, a liquid-state precursor chemical is stored in a buffer vessel and is pressurized to supply the chemical to a treatment unit through a supply pipe passing through a vaporizer.

When all of the precursor chemical stored in the buffer vessel is consumed, the operation of the depositing apparatus is suspended to replace the buffer vessel with a new one or to refill the buffer vessel. In the former case, the operating rate of the depositing apparatus decreases since the operation of the deposition apparatus is suspended during the replacement of the buffer vessel. In the latter case, the amount of a chemical that can be refilled in the buffer vessel decreases as the number of refillings increases since the pressure inside the buffer vessel increases in proportion to the number of refillings due to pressurizing gas. Therefore, the buffer vessel may have to be refilled more frequently as the number of refillings increases, and it may take a large amount of time to keep the rate of chemical supply from the buffer vessel to the treatment unit at a constant level due to the high pressure of the buffer vessel.

### SUMMARY OF THE INVENTION

Embodiments of the present invention provide a liquid supplying unit and method for efficiently supplying a chemical, a facility for treating substrates with the liquid supplying unit, and a method for treating substrates.

Embodiments of the present invention also provide a liquid supplying unit and method for efficiently refilling a buffer vessel with a chemical without a decrease in operating rate, a facility for treating substrates with the liquid supplying unit, and a method for treating substrates.

Other advantages, objects, and features of the embodiments of the invention will become apparent to those having ordinary skill in the art upon examination of the following or may be learned from practice thereof.

In one aspect. a liquid supplying unit comprises: a buffer vessel including a void space for receiving liquid; a liquid inlet pipe through which liquid is supplied to the buffer vessel from a liquid storage container; a liquid supply pipe through which the liquid present in the buffer vessel is supplied to a predetermined unit; a gas inlet pipe through which a pressurizing gas is supplied to the buffer vessel from a gas storage container for pressurizing the liquid present in the buffer vessel to expel the liquid from the buffer vessel through the liquid supply pipe; and a vent line connected to the buffer vessel for discharging the pressurizing gas from the buffer vessel.

The liquid supplying unit can further comprise a pressure measuring member that measures a pressure inside the buffer vessel. The pressure measuring member can be a pressure gauge installed at the vent line.

The liquid supplying unit can further comprise a level measuring member that measures a height of the liquid present in the buffer vessel.

The level measuring member can comprise: a lower sensor detecting the height of the liquid present in the buffer vessel for determining a time to start supplying liquid from the liquid storage container to the buffer vessel; and an upper sensor detecting the height of the liquid present in the buffer vessel for determining a time to stop the supplying of the liquid from the liquid storage container to the buffer vessel.

The liquid supplying unit can further comprise a pump installed at the vent line for discharging the pressurizing gas from the buffer vessel.

In another aspect, a facility for treating substrates comprises: a treatment unit including a process chamber in which substrates are treated; a buffer vessel including a void space for receiving a liquid chemical; a chemical inlet pipe through which a liquid chemical is supplied to the buffer vessel from a liquid storage container; a chemical supply pipe through which the liquid chemical present in the buffer vessel is supplied to the treatment unit, the chemical supply pipe including a vaporizer to vaporize the liquid chemical; a gas inlet pipe through which a pressurizing gas is supplied to the buffer vessel from a gas storage container for pressurizing the liquid chemical present in the buffer vessel to expel the liquid chemical from the buffer vessel through the chemical supply pipe; and a vent line connected to the buffer vessel for discharging the pressurizing gas from the buffer vessel.

The facility can further comprise a vent pump installed at the vent line for discharging the pressurizing gas from the buffer vessel. The facility can further comprise a process pump that maintains the process chamber of the treatment unit at a preset pressure. The facility can further comprise a connection pipe branching off from the chemical supply pipe and connected to the vent pump.

The facility can further comprise a pressure measuring member that measures a pressure inside the buffer vessel. The pressure measuring member can be a pressure gauge installed at the vent line.

The facility can further comprise: a lower sensor detecting a height of the liquid chemical present in the buffer vessel for determining a time to start supplying a liquid chemical from the liquid storage container to the buffer vessel; and an upper sensor detecting the height of the liquid chemical present in the buffer vessel for determining a time to stop the supplying of the liquid chemical from the liquid storage container to the buffer vessel.

The facility can further comprise: a pressure measuring member that measures a pressure inside the buffer vessel; a lower sensor detecting a height of the liquid chemical present in the buffer vessel for determining a time to start supplying a liquid chemical from the liquid storage container to the buffer vessel; valves installed at the chemical inlet pipe, the chemical supply pipe, the gas inlet pipe, and the vent line, respectively; and a controller receiving sensing signals from the lower sensor and the pressure measuring member and controlling opening/closing of the valves.

In another aspect, a liquid supplying method for supplying liquid from a buffer vessel to a unit external to the buffer vessel by pressurizing the liquid present in the buffer vessel using gas supplied to the buffer vessel, the liquid supplying method comprises: if the amount of the liquid present in the buffer vessel is reduced to less than a reference level, refilling the buffer vessel by supplying liquid to the buffer vessel; and if a preset condition is satisfied while repeating the refilling of the buffer vessel, discharging the gas from the buffer vessel through a vent line.

The preset condition can comprise a pressure condition, and the discharging of the gas from the buffer vessel can be performed when a pressure inside the buffer vessel is equal to or greater than a reference pressure.

The discharging of the gas from the buffer vessel can be performed using a depressurizing member connected to the vent line.

In another aspect, a method for treating substrates comprises: performing a predetermined process on substrates in a treatment unit using a vaporized chemical prepared by vaporizing a liquid chemical supplied from a buffer vessel; supplying the liquid chemical from the buffer vessel to the treatment unit by pressurizing the liquid chemical present in the buffer vessel using gas supplied to the buffer vessel; if the amount of the liquid chemical present in the buffer vessel reduces to less than a reference level, refilling the buffer vessel by supplying a liquid chemical to the buffer vessel; and if a preset condition is satisfied while repeating the refilling of the buffer vessel, discharging the gas from the buffer vessel through a vent line.

The predetermined process can be a deposition process for depositing organic metal on the substrates, and the chemical is a precursor of the organic metal.

After the liquid chemical is stably vaporized, the vaporized chemical can be supplied to the treatment unit, and an initial amount of the vaporized chemical that is unstably vaporized can be discharged through the pump connected to the vent line.

The preset condition can comprise a pressure condition inside the buffer vessel, and the discharging of the gas from the buffer vessel can be performed when a pressure measured inside the buffer vessel is equal to or greater than a first reference pressure.

The pressure inside the buffer vessel can be measured after it is detected that a height of the liquid chemical present in the buffer vessel reaches a first level, and then the discharging of the gas from the buffer vessel can be performed according to the measured pressure.

If the predetermined process continues in the treatment unit when it is detected that the height of the liquid chemical present in the buffer vessel reaches the first level, the discharging of the gas from the buffer vessel can be performed according to a pressure inside the buffer vessel measured after the predetermined process is completed.

The discharging of the gas from the buffer vessel can comprise: opening a valve installed at the vent line for a predetermined time to discharge the gas from the buffer vessel; measuring a pressure inside the buffer vessel after closing the valve; and if the measured pressure is greater than a second reference pressure, re-opening the valve for the predetermined time, wherein the measuring of the pressure and the re-opening of the valve are repeated until the pressure inside the buffer vessel becomes equal to or less than the second reference pressure.

The valve can be installed at a chemical inlet pipe connected between a liquid storage container and the buffer vessel, and when the valve is closed after a liquid chemical is supplied from the liquid storage container to the buffer vessel, a portion of the chemical inlet pipe between the valve and the liquid storage container can be filled with the liquid chemical remaining therein.

### BRIEF DESCRIPTION OF THE FIGURES

The accompanying figures are included to provide a further understanding of the embodiments of the present invention, and are incorporated in and constitute a part of this specification. The drawings illustrate exemplary embodiments of the present invention and, together with the description, serve to explain principles of the present invention. In the figures:

FIG. 1 illustrates a facility for treating substrates according to an embodiment of the present invention;

FIG. 2 schematically illustrates a treatment unit of the facility of FIG. 1;

FIG. 3 illustrates a modified version of the embodiment of the facility of FIG. 1;

FIG. 4 illustrates operations of the substrate treating facility;

FIGS. 5 through 9 illustrate open/close states of an automatic valves according to operations of the substrate treating facility; and

FIGS. 10A and 10B illustrate a relationship between the internal pressure of a buffer vessel and the amount of a chemical refilled in the buffer vessel for comparing the case where the buffer vessel is refilled with the chemical without a release of gas from the buffer vessel with the case where the buffer vessel is refilled with the chemical after gas is released from the buffer vessel.

### DETAILED DESCRIPTION OF EMBODIMENTS

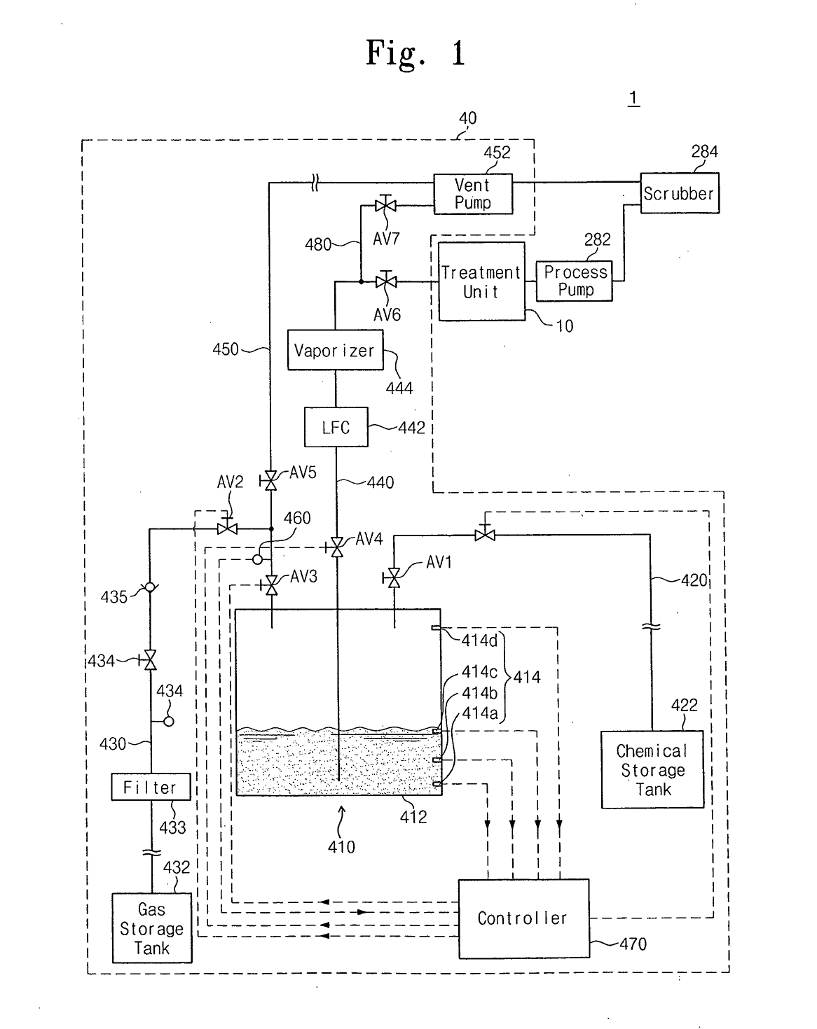

Embodiments of the present invention will be described below in more detail with reference to FIGS. 1 through 10B. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration.

In the following descriptions, an organic metal deposition facility used for depositing an organic metal layer on a substrate in a semiconductor device manufacturing process is selected as an exemplary facility for explaining embodiments of the present invention. However, the scope of the present invention is not limited to the organic metal deposition facility. Embodiments of the present invention can be applied to various liquid supplying units that supply liquid from a buffer vessel to a location external to the buffer vessel by pressurizing the buffer vessel with gas.

FIG. 1 illustrates a facility 1 for treating substrates according to an embodiment of the present invention. Referring to FIG. 1, the substrate treating facility 1 includes a treatment unit 10 and a liquid supplying unit 40. The treatment unit 10 provides a chamber or location whereby an organic metal layer can be deposited on a substrate. The liquid supplying unit 40 supplies a chemical (organic metal) to the treatment unit 10 for the deposition of the organic metal layer. A liquid-state chemical supplied from the liquid supplying unit 40 is vaporized by a vaporizer 444 and then is supplied to the treatment unit 10.

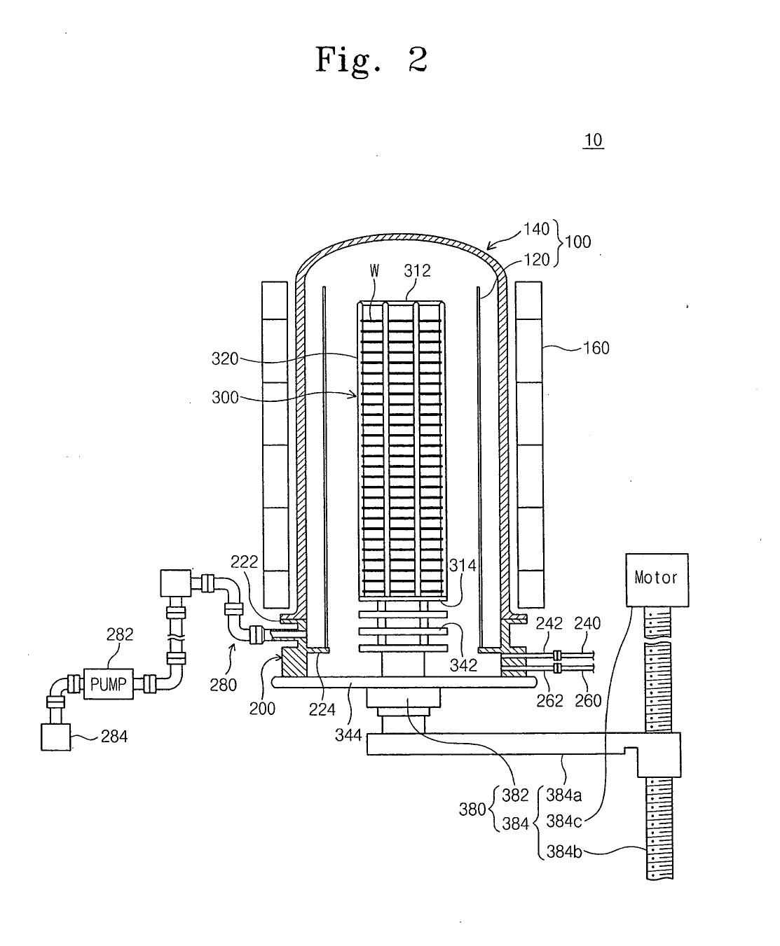

FIG. 2 is a cross-sectional view schematically illustrating the treatment unit 10 of the facility of FIG. 1, according to an embodiment of the present invention. The treatment unit 10 includes a process chamber 100 in which a deposition process is performed. The process chamber 100 includes an inner tube 120 formed of quartz, and an outer tube 140. The inner tube 120 has a hollow cylindrical shape with opened top and bottom ends. The outer tube 140 surrounds the inner tube 120 at a predetermined distance from the inner tube 120. The outer tube 140 has a hollow cylindrical shape with an opened bottom end. A heater 160 is disposed around the outer tube 140. The heater 160 operates to maintain the process chamber 100 at a predetermined process temperature.

Wafers (W) to be processed are loaded in a boat 300. The boat 300 includes a horizontal upper plate 312 and a lower plate 314 disposed at an opposite side of the upper plate 312. A plurality of vertical supports 320 are disposed between the upper and lower plates 312 and 314. Slots are formed in each of the vertical supports 320 for receiving edges of the wafers (W). The number of slots may be about 50 to 100 for each of the vertical supports 320. Heat release plates 342 are disposed under the lower plate 314. The heat release plates 342 are formed of quartz and are horizontally disposed. The boat 300 is supported by a cap 344. The cap 344 has a plate shape. When the boat 300 is inserted into the inner tube 120, the cap 344 makes contact with a bottom surface of a flange 200 to seal the process chamber 100. A driving unit 380 is connected to the cap 344. The driving unit 380 includes a motor 382 for rotating the cap 344 and a lifter 384 for moving the cap 344 in a vertical direction. The lifter 344 includes a motor 384c, a screw 384b rotated by the motor 384c, and a bracket 384a receiving the screw 384b and connected to the cap 344. When the screw 384b rotates, the bracket 384a moves linearly in a vertical direction.

The flange 200 is disposed under the inner and outer tubes 120 and 140 to support the inner and outer tubes 120 and 140. The flange 200 includes a penetration through hole in a middle portion. The process chamber 100 is connected to a waiting chamber (not shown) through the penetration hole of the flange 200. The wafers (W) are loaded into the boat 300 from the waiting chamber and are moved into and out of the inner tube 120. The flange 200 includes an outer base 222 supporting the outer tube 140 and an inner base 224 supporting the inner tube 120. The outer base 222 has a ring shape and extends outward from an upper end of the flange 200. The inner base 224 has a ring shape and extends inward from an inner surface of the flange 200. Ports 242 and 262 are formed at a side of the flange 200. The port 242 is connected to a supply pipe 240 to receive a process gas, and the port 262 is connected to a supply pipe 260 to receive a purge gas. A discharge pipe 280 is connected to the other side of the flange 200. A process pump 282 is connected to the discharge pipe 280 to maintain the interior of the process chamber 100 at a low pressure during operation and discharge by-products from the process chamber 100 through the discharge pipe 280. A scrubber 284 can be connected to the discharge pipe 280 to clean gas discharged from the process chamber 100.

While a process gas including a precursor is introduced into the inner tube 120 and flows upward, the precursor is deposited on the wafers (W) loaded on the boat 300. Any remaining process gas flows downward along a path between the inner tube 120 and the outer tube 140 and is discharged external to the process chamber 100 through the discharge pipe 280.

For example, for depositing hafnium oxide layers on the wafers (W), an oxidation gas and a hafnium precursor source (chemical) gas can be used as process gases. Tetra ethyl methyl amino hafnium (TEMAHf) can be used as the hafnium precursor source, and oxygen (O₂) gas can be used as the oxidation gas. Further, argon or nitride gas can be used as the purge gas.

In detail, a hafnium precursor source gas is first supplied to the process chamber 100 to form thin (atomic level) hafnium precursor layers on the wafers (W). Next, purge gas is supplied to the process chamber 100 to purge the process chamber 100. Next, oxygen gas is supplied to the process chamber 100 to oxidize the thin hafnium precursor layers to form atom-level hafnium oxide layers on the wafers (W). Then, purge gas is supplied to the process chamber 100 to remove by-products produced during the formation of the hafnium oxide layers from the process chamber 100. In one deposition cycle, hafnium precursor source gas, purge gas, oxygen gas, and purge gas are sequentially supplied to the process chamber 100 as described above. This deposition cycle can be repeated to grow the hafnium oxide layer to a desired thickness.

In the above-described example, tetra ethyl methyl amino hafnium (TEMAHf) is used as the precursor source gas. However, other kinds of precursor source gas can be used depending on the type of a thin layer to be deposited. For example, when an aluminum oxide layer or a zirconium oxide layer is deposited, trimethylaluminum (TMAl) or tetra ethyl methyl amino zirconium (TEMAZr) can be used as the precursor source gas. In addition, when a thin nitride layer is deposited, ammonia or nitride gas can be used instead of oxygen gas.

The precursor source gas is supplied in the form of a liquid chemical and is vaporized by the vaporizer 444 of the liquid supplying unit 40. Then, the precursor source gas is supplied to the process chamber 100 from the liquid supplying unit 40. Hereinafter, an exemplary structure of the liquid supplying unit 40 will be described in more detail with reference to FIG. 1.

The liquid supplying unit 40 includes a buffer vessel 410, a chemical inlet pipe (a liquid inlet pipe) 420, a gas inlet pipe 430, a chemical supply pipe (a liquid supply pipe) 440, and a vent line 450. The buffer vessel 410 can have a barrel shape to receive and retain a chemical. The buffer vessel 410 is formed of corrosion-resistant stainless steel, and has strength for resisting high pressure. A level measuring member 414 is installed in the buffer vessel 410 for measuring the height of a chemical filled in the buffer vessel 410. Sensors can be used as the level measuring member 414 for determining whether the height of the chemical reaches a predetermined level. For example, the level measuring member 414 can include a lowermost sensor 414a, a lower sensor 414b, an upper sensor 414c, and an uppermost sensor 414d. The lower sensor 414b is used to detect whether the height of the chemical reaches a first level. When the height of the chemical reaches the first level, it may be necessary to refill the buffer vessel 410. For example, it can be preset such that about 25% of the storage volume of the buffer vessel 410 is filled with the chemical at the first level. The upper sensor 414c is used to detect whether the height of the chemical reaches a second level. When the height of the chemical reaches the second level, it may be necessary to stop supplying of a chemical to the buffer vessel 410. For example, it can be preset such that about 40% of the storage volume of the buffer vessel 410 is filled with the chemical at the second level. The lowermost and uppermost sensors 414a and 414d are used to detect extremely low and high heights of the chemical that are not suitable for performing an operation.

The chemical inlet pipe 420 is connected to a chemical storage container 422 such that a chemical can be supplied from the chemical storage container 422 to the buffer vessel 410. The chemical inlet pipe 420 passes through an upper wall of the buffer vessel 410 such that an end of the chemical inlet pipe 420 is located at an upper portion of the buffer vessel 410. The chemical inlet pipe 420 is used to refill the buffer vessel 410 with a chemical according to preset conditions. The chemical storage container 422 stores a chemical (liquid-state organic metal). As described above, the chemical can be TEMAHf, TEMAZr, or TMAl.

The gas inlet pipe 430 is connected to a gas storage container 432 such that gas can be supplied from the gas storage container 432 to the buffer vessel 410. A chemically stable gas such as helium (He), argon (Ar), or nitride (N₂) gas may be filled in the gas storage container 432. The gas inlet pipe 430 passes through the upper wall of the buffer vessel 410 such that an end of the gas inlet pipe 430 is located at an upper portion of the buffer vessel 410. The chemical inlet pipe 420 is used to refill the buffer vessel 410 with a chemical according to preset conditions. The chemical storage container 422 stores a chemical (liquid-state organic metal). A filter 433, a needle valve 434, and a check valve 435 are installed at the gas inlet pipe 430. The filter 433 removes pollutants from gas when the gas is supplied from the gas storage container 432 to the buffer vessel 410. The needle valve 434 is used to control the flow rate of the gas. The check valve 435 prevents a backflow of the gas from the buffer vessel 410 to the gas storage container 432. Gas is supplied from the gas storage container 432 to the buffer vessel 410 to pressurize the buffer vessel 410 such that the chemical present and filled in the buffer vessel 410 can be supplied to the process chamber 100 through the chemical supply pipe 440.

The chemical supply pipe 440 passes through the upper wall of the buffer vessel 410 and extends to a lower portion of the buffer vessel 410. The vaporizer 444 is installed at the chemical supply pipe 440 for vaporize the chemical supplied from the buffer vessel 410. A flowrate controller 442 such as a liquid flow controller (LFC) is installed at the chemical supply pipe 440 to control the amount of chemical flowing through the chemical supply pipe 440.

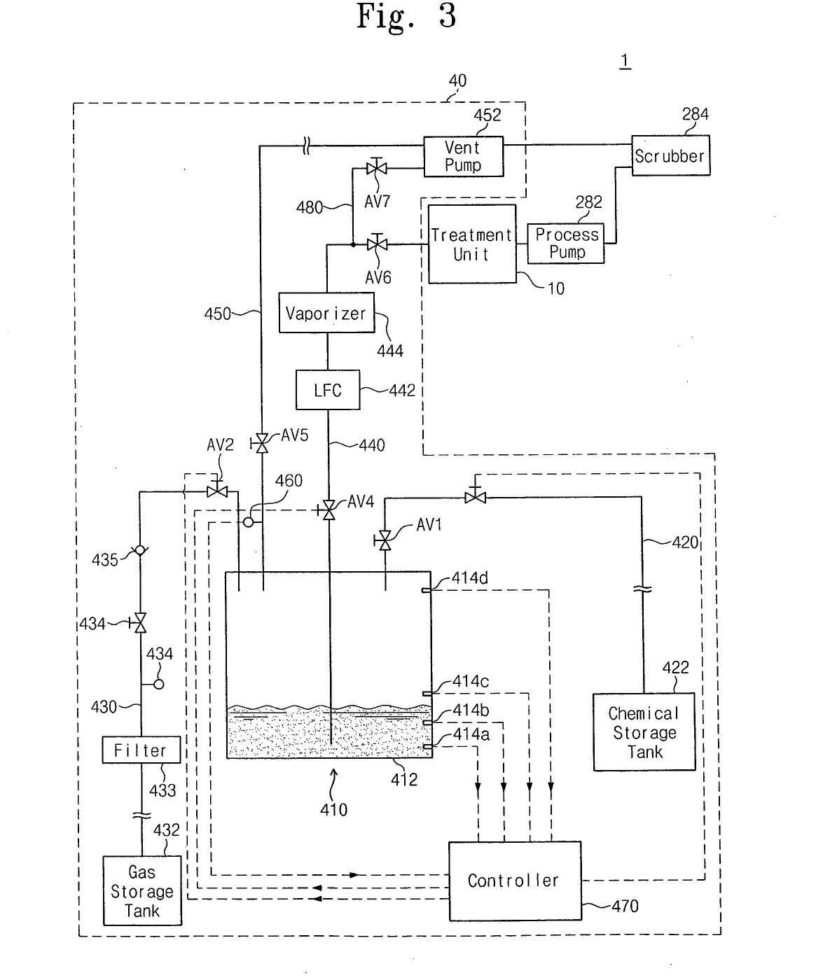

As the number of refillings of the buffer vessel 410 increases, the internal pressure of the buffer vessel 410 increases. In detail, gas is supplied to the buffer vessel 410 for pressurizing the chemical filled in the buffer vessel 410 to supply the chemical from the buffer vessel 410 to the process chamber 100, and the gas is not discharged after the chemical is supplied to the process chamber 100. In this state, the buffer vessel 410 is refilled with a chemical, and gas is supplied to the buffer vessel 410 again to supply the chemical from the buffer vessel 410 to the process chamber 100 through the chemical supply pipe 440. Therefore, the internal pressure of the buffer vessel 410 increases as the number of refillings of the buffer vessel 410 increases. For this reason, the vent line 450 is connected to the buffer vessel 410 to discharge gas from the buffer vessel 410 at a preset condition. A vent pump 452 is installed at the vent line 450 to discharge gas from the buffer vessel 410. The vent line 450 is connected to the above-described scrubber 284. In one embodiment, the vent line 450 may branch off from the gas inlet pipe 430. In another embodiment, the vent line 450 can be provided independently of the gas inlet pipe 430 as shown in FIG. 3.

Automatic valves AV1, AV2, and AV4 are installed at the chemical inlet pipe 420, the gas inlet pipe 430, and the chemical supply pipe 440, respectively. Further, automatic valves AV3 and AV5 are installed at the vent line 450. The automatic valve AV3 is located between the buffer vessel 410 and a branch point where the vent line 450 branches off from the gas inlet pipe 430, and the automatic valve AV5 is located between the branch point and the vent pump 452. The automatic valves AV1, AV2, AV3, AV4, and AV5 are automatically opened and closed in response to the controller 470.

In one embodiment, the above-described preset condition for discharging gas from the buffer vessel 410 may be the pressure of the buffer vessel 410 before the buffer vessel 410 is refilled with a chemical. A pressure measuring member connected to the controller for providing a feedback signal thereto can be used to measure the pressure of the buffer vessel 410. A pressure gauge 460 can be used as the pressure measuring member. The pressure gauge 460 can be installed at the gas inlet pipe 430 between the automatic valve AV3 and the branch point. In the case where the vent line 450 is provided independently of the gas inlet pipe 430, the pressure gauge 460 is installed at the vent line 450. Alternatively, the pressure gauge 460 can be installed in the buffer vessel 410 instead of the gas inlet pipe 430 or the vent line 450. In this manner, the pressure of the buffer vessel 410 can be monitored in real time.

The condition for discharging gas from the buffer vessel 410 can be changed depending on a number of factors. For example, the number of refillings of the buffer vessel 410 or the number of processings of the process chamber 100 can be used as the condition for determining the timing of discharging gas from the buffer vessel 410.

The vent pump 452 and the chemical supply pipe 440 are connected through a connection pipe 480. The connection pipe 480 branches off from the chemical supply pipe 440 at a point between the vaporizer 444 and the treatment unit 10. At an early stage, a chemical being vaporized at the vaporizer 444 is not directed to the treatment unit 10. Instead, the vaporized chemical is discharged through the connection pipe 480 until the chemical is stably vaporized at the vaporizer 444. An automatic valve AV6 is installed at the chemical supply pipe 440 between the treatment unit 10 and a branch point where the connection pipe 480 branches off from the chemical supply pipe 440. An automatic valve AV7 is installed at the connection pipe 480. Gas discharged from the buffer vessel 410 and unstable vapor chemical can be discharged through the vent pump 452 instead of the process pump 282. Therefore, the process pump 282 can be cleaned less frequently, and thus the operating rate of the process pump 282 can be increased.

A controller 470 controls operations of the liquid supplying unit 40 and the treatment unit 10. The controller 470 receives information related to the pressure of the buffer vessel 410 and the fill height of a chemical present in the buffer vessel 410 from the pressure gauge 460 and the level measuring member 414. The controller 470 controls opening and closing activities of the automatic valves AV1, AV2, AV3, AV4, AV5, AV6, and AV7 (note that dashed lines between the controller 490 and valves AV1, AV5, AV6, and AV7, although not shown in FIG. 1, for the purpose of clarity, are actually present for representing automated control of the valves).

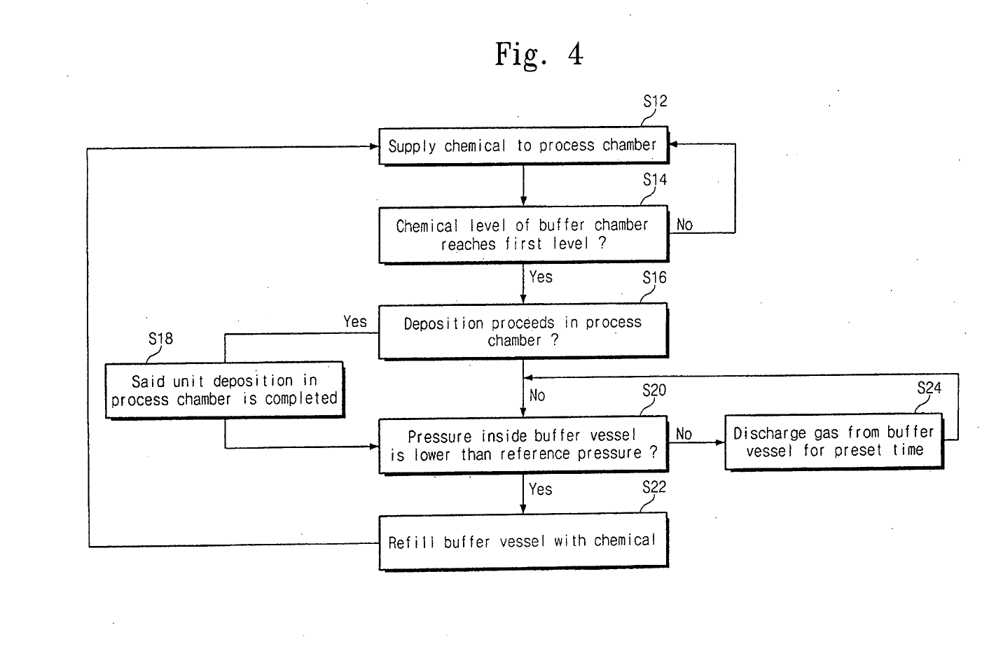

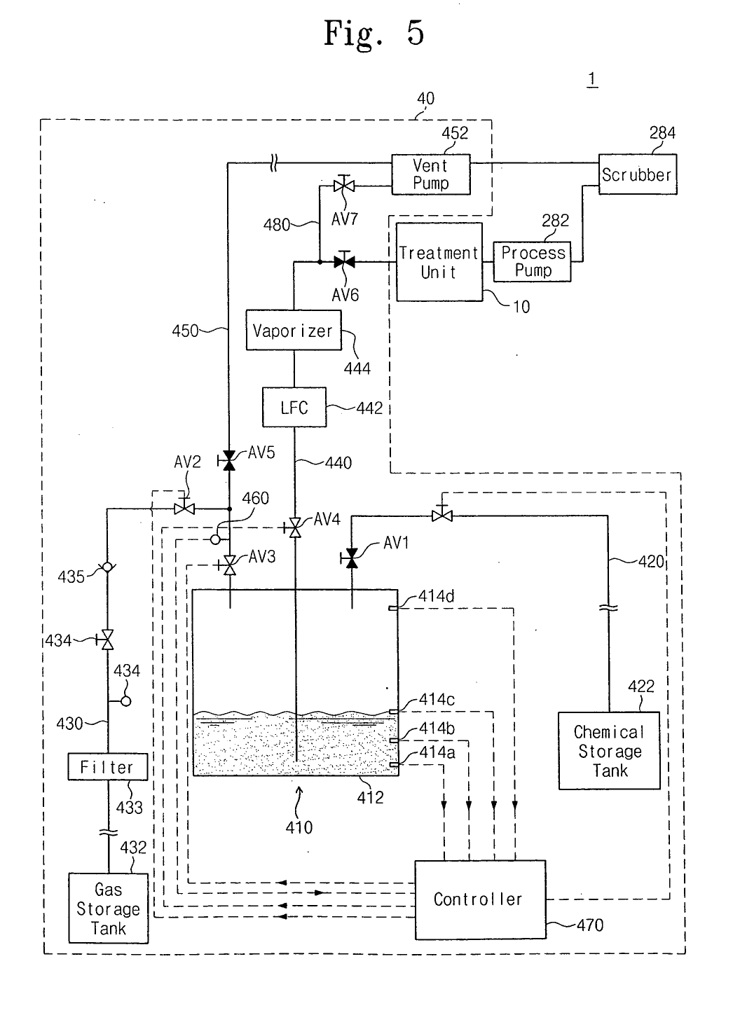

A method of supplying a chemical from the liquid supplying unit 40 to the treatment unit 10 will now be described with reference to FIGS. 4 through 9. FIG. 4 is a flowchart for explaining how the liquid supplying unit 40 is refilled with a chemical, and FIGS. 5 through 9 illustrate open/close states of the automatic valves AV1, AV2, AV3, AV4, AV5, AV6, and AV7 for supplying a chemical. In FIGS. 5 through 9, a darkened valve is a closed valve, and a non-darkened valve is an opened valve.

After the buffer vessel 410 is filled with a liquid chemical, gas is supplied to the buffer vessel 410 to increase the pressure of the buffer vessel 410. In response to the increase of the pressure of the buffer vessel 410, the chemical is delivered to the chemical supply pipe 440. Then, the chemical is vaporized at the vaporizer 444 and is supplied to the process chamber 100 of the treatment unit 10. Here, the vaporized chemical is not directly supplied to the treatment unit 10. Instead, the vaporized chemical is discharged through the vent pump 452 until stable chemical vaporization is achieved at the vaporizer 444. For this operation, the automatic valves AV2, AV3, AV4, and AV7 are opened, and the automatic valves AV1, AV5, and AV6 are closed (Refer to FIG. 5).

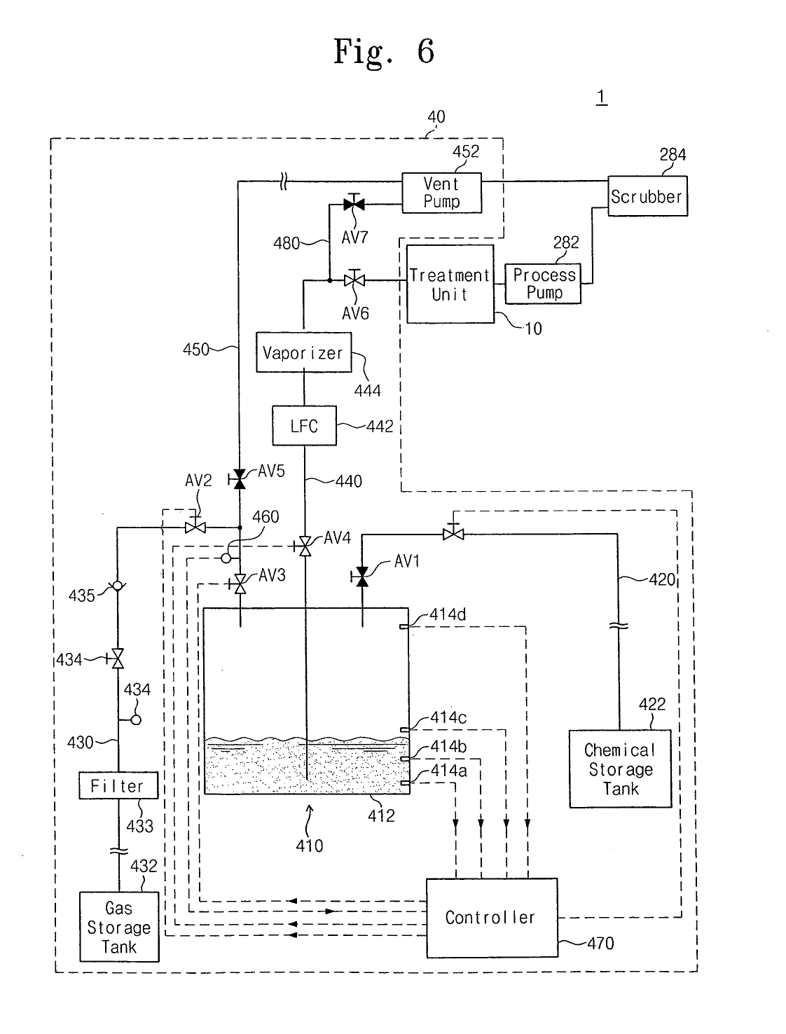

With reference to FIG. 6, after the chemical is stably vaporized at the vaporizer 444, in operation S12, the vaporized chemical is supplied to the process chamber 100 of the treatment unit 10 for a deposition process. Here, the automatic valves AV2, AV3, AV4, and AV6 are opened, and the automatic valves AV1, AV5, and AV7 are closed.

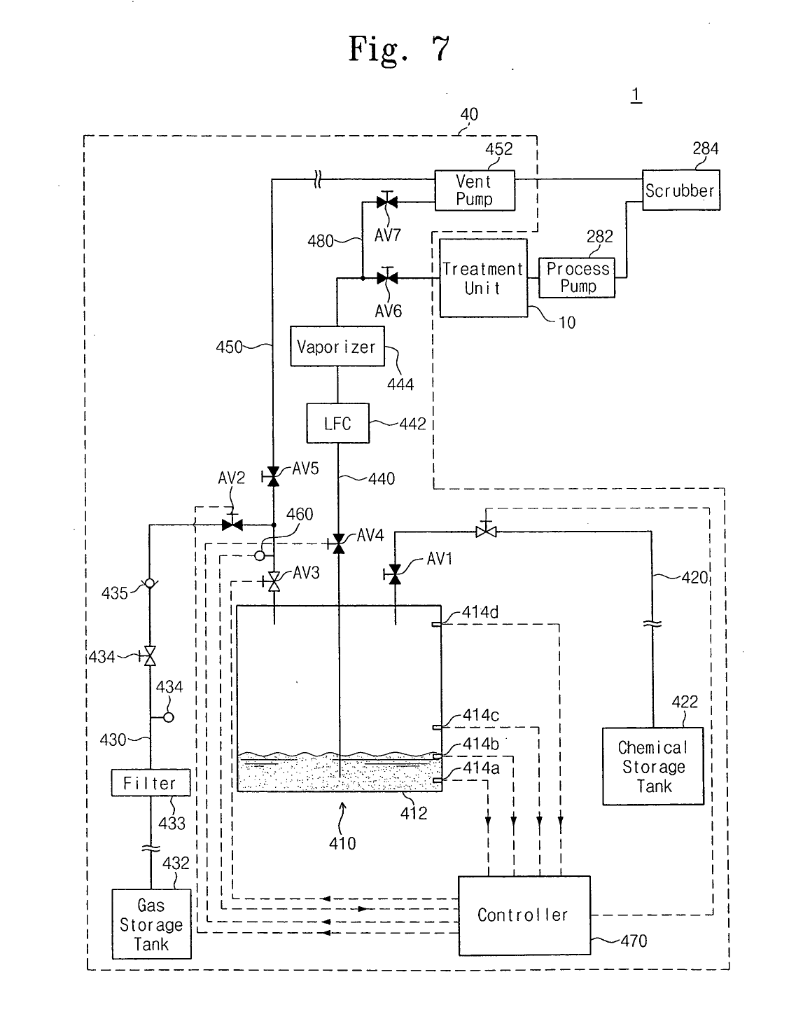

As the deposition process proceeds, the amount of chemical present in the buffer vessel 410 decreases. In operation S14, the lower sensor 414b detects whether the height of the chemical present in the buffer vessel 410 is reduced to the first level. If the height of the chemical present in the buffer vessel 410 is reduced to the first level, the buffer vessel 410 is to be refilled with a chemical in operation S22. Before the buffer vessel 410 is refilled, in operation S16, it is determined whether a deposition process is being performed on wafers (W) in the process chamber 100. If a deposition process is not being performed on the wafers (W) in the process chamber 100, the pressure of the buffer vessel 410 is detected, and the controller 470 determines whether the detected pressure is lower than a first reference pressure in operation S20. If the deposition process is being performed on the wafers (W) in the process chamber 100, the pressure of the buffer vessel 410 is detected after the deposition process for the wafers (W) is completed in operation S18. To detect the pressure of the buffer vessel 410, the automatic valve AV3 is opened, and the automatic valves AV1, AV2, AV4, AV5, AV6, and AV7 are closed, as shown in FIG. 7.

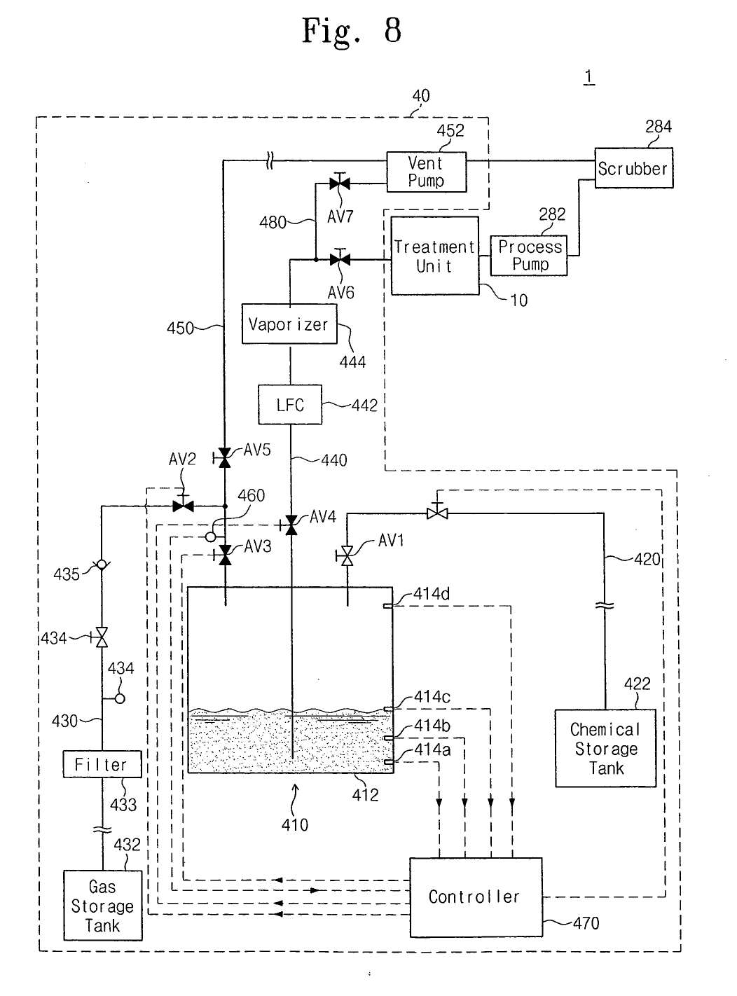

When it is determined in operation S20 that the pressure of the buffer vessel 410 is lower than the first reference pressure, it is considered that the pressure of the buffer vessel 410 is within an allowable pressure range so that gas would not be discharged from the buffer vessel 410. Then, in operation S22, the buffer vessel 410 is refilled with a chemical until the height of the chemical is raised to a second level. At this time, the automatic valve AV1 is opened, and the automatic valves AV2, AV3, AV4, AV5, AV6, and AV7 are closed, as shown in FIG. 8.

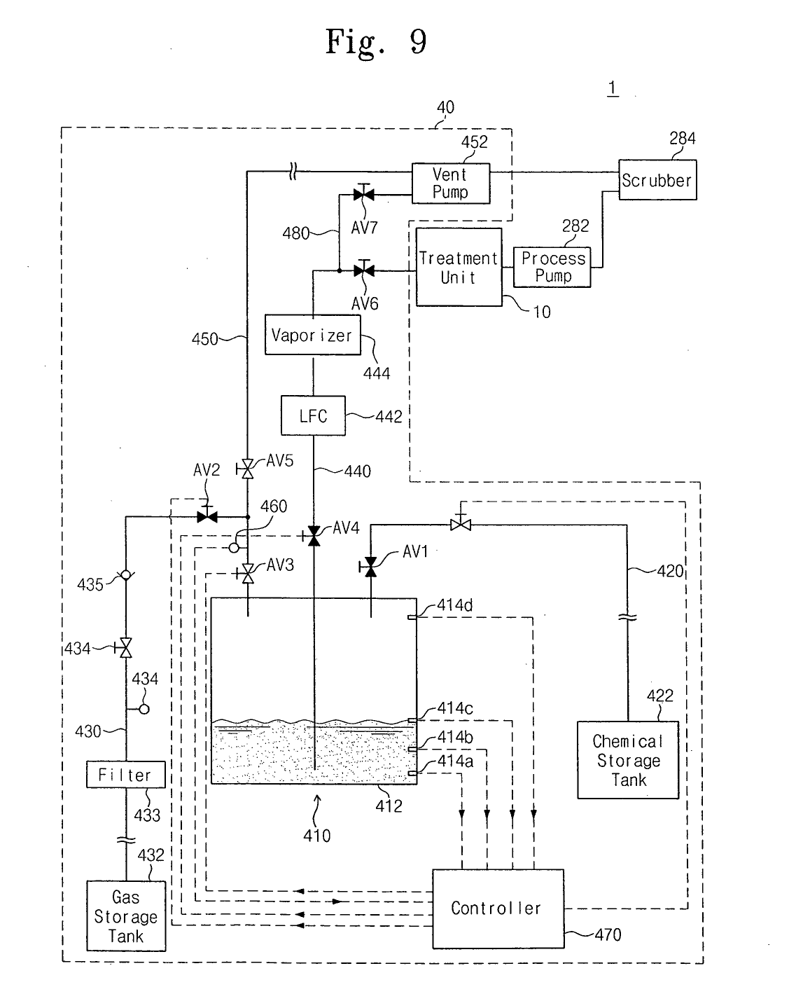

When it is determined in operation S20 that the pressure of the buffer vessel 410 is higher than the first reference pressure, gas is discharged from the buffer vessel 410 through the vent line 450 in operation S24. At this time, the automatic valves AV3 and AV5 are opened, and the automatic valves AV1, AV2, AV4, AV6, and AV7 are closed (refer to FIG. 9). In operation S24, the automatic valves AV3 and AV5 are opened for a preset time to discharge gas from the buffer vessel 410 through the vent line 450. Thereafter, the automatic valve AV5 is closed, and the pressure of the buffer vessel 410 is measured again through the opened automatic valve AV3. If the pressure of the buffer vessel 410 is lower than a second reference pressure, operation S24 is terminated, and the procedure returns to operation S22 for refilling the buffer vessel 410 with a chemical. If the pressure of the buffer vessel 410 is higher than the second reference pressure, the automatic valves AV3 and AV5 are opened again for the preset time to discharge gas from the buffer vessel 410.

The first and second reference pressures can be equal pressure values. Alternatively, the first and second reference pressures can be different.

After the buffer vessel 410 is refilled in operation S22, any chemical remaining in the chemical inlet pipe 420 can be collected to the chemical storage container 422. However, in this case, many particles can be present in the chemical inlet pipe 420. It may take a lot of time to remove the particles from the chemical inlet pipe 420, and thus the operating rate of the liquid supplying unit 40 may decrease. For this reason, the automatic valve AV1 is closed after the buffer vessel 410 is refilled in operation S22 such that a portion of the chemical inlet pipe 420 between the chemical storage container 422 and the automatic valve AV1 can be filled with the remaining chemical for preventing generation of particles. Therefore, contamination of the chemical inlet pipe 420 can be prevented, and reduction of the operation rate of the liquid supplying unit 40 can be prevented.

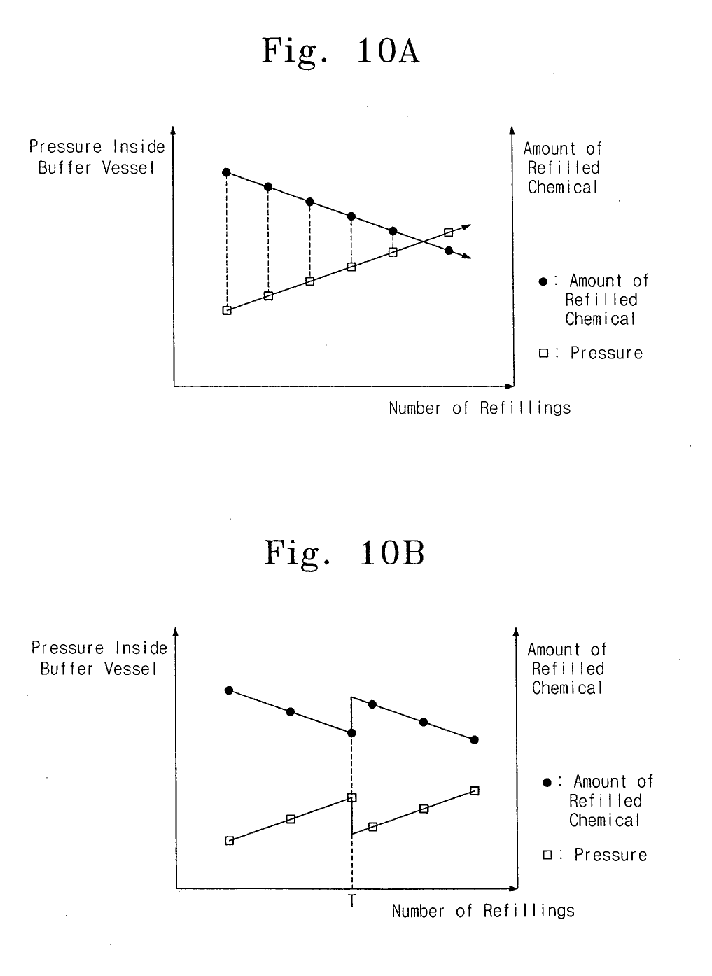

FIG. 10A illustrates a relationship between the internal pressure of the buffer vessel 410 and the amount of a chemical present in the buffer vessel 410 after a refill operation in the case where the buffer vessel 410 is refilled with the chemical without a release of gas from the buffer vessel 410, and FIG. 10B illustrates a relationship between the internal pressure of the buffer vessel 410 and the amount of a chemical refilled in the buffer vessel 410 in the case where the buffer vessel 410 is refilled with the chemical after gas is released from the buffer vessel 410 through the vent line 450. Referring to FIG. 10A, the buffer vessel 410 is periodically refilled without discharging gas from the buffer vessel 410. Therefore, as the number of refillings of the buffer vessel 410 increases, the internal pressure of the buffer vessel 410 increases. Thus, the amount of a chemical refilled in the buffer vessel 410 reduces in reverse proportion to the internal pressure of the buffer vessel 410. In contrast, referring to FIG. 10B, when gas is released from the buffer vessel 410 (refer to symbol T in FIG. 10B), the internal pressure of the buffer vessel 410 is reduced, and thus the amount of a chemical refilled in the buffer vessel 410 increases.

According to embodiments of the present invention, a chemical can be continuously supplied so that the operating rate of the substrate treating facility can be increased.

Furthermore, the time necessary for initially stabilizing a chemical supply can be reduced.

In addition, the buffer vessel can be refilled less frequently so that the operating rate of the substrate treating facility can be increased.

The above-disclosed subject matter is to be considered illustrative, and not restrictive, and the appended claims are intended to cover all such modifications, enhancements, and other embodiments, which fall within the true spirit and scope of the present invention. Thus, the scope of the present invention is to be determined by the broadest permissible interpretation of the following claims and their equivalents, and shall not be restricted or limited by the foregoing detailed description.

What is claimed is:

1. A liquid supplying unit comprising:
a buffer vessel including a void space for receiving liquid;
a liquid inlet pipe through which liquid is supplied to the buffer vessel from a liquid storage container;
a liquid supply pipe through which the liquid present in the buffer vessel is supplied to a predetermined unit;
a gas inlet pipe through which a pressurizing gas is supplied to the buffer vessel from a gas storage container for pressurizing the liquid present in the buffer vessel to expel the liquid from the buffer vessel through the liquid supply pipe; and
a vent line connected to the buffer vessel for discharging the pressurizing gas from the buffer vessel.

2. The liquid supplying unit of claim 1, further comprising a pressure measuring member that measures a pressure inside the buffer vessel.

3. The liquid supplying unit of claim 2, wherein the pressure measuring member is a pressure gauge installed at the vent line.

4. The liquid supplying unit of claim 1, further comprising a level measuring member that measures a height of the liquid present in the buffer vessel.

5. The liquid supplying unit of claim 4, wherein the level measuring member comprises:
a lower sensor detecting the height of the liquid present in the buffer vessel for determining a time to start supplying liquid from the liquid storage container to the buffer vessel; and
an upper sensor detecting the height of the liquid present in the buffer vessel for determining a time to stop the supplying of the liquid from the liquid storage container to the buffer vessel.

6. The liquid supplying unit of claim 1, further comprising a pump installed at the vent line for discharging the pressurizing gas from the buffer vessel.

7. A facility for treating substrates, comprising:
a treatment unit including a process chamber in which substrates are treated;
a buffer vessel including a void space for receiving a liquid chemical;
a chemical inlet pipe through which a liquid chemical is supplied to the buffer vessel from a liquid storage container;
a chemical supply pipe through which the liquid chemical present in the buffer vessel is supplied to the treatment unit, the chemical supply pipe including a vaporizer to vaporize the liquid chemical;
a gas inlet pipe through which a pressurizing gas is supplied to the buffer vessel from a gas storage container for pressurizing the liquid chemical present in the buffer vessel to expel the liquid chemical from the buffer vessel through the chemical supply pipe; and
a vent line connected to the buffer vessel for discharging the pressurizing gas from the buffer vessel.

8. The facility of claim 7, further comprising a vent pump installed at the vent line for discharging the pressurizing gas from the buffer vessel.

9. The facility of claim 8, further comprising a process pump that maintains the process chamber of the treatment unit at a preset pressure.

10. The facility of claim 9, further comprising a connection pipe branching off from the chemical supply pipe and connected to the vent pump.

11. The facility of claim 7, further comprising a pressure measuring member that measures a pressure inside the buffer vessel.

12. The facility of claim 11, wherein the pressure measuring member is a pressure gauge installed at the vent line.

13. The facility of claim 7, further comprising:
a lower sensor detecting a height of the liquid chemical present in the buffer vessel for determining a time to start supplying a liquid chemical from the liquid storage container to the buffer vessel; and
an upper sensor detecting the height of the liquid chemical present in the buffer vessel for determining a time to stop the supplying of the liquid chemical from the liquid storage container to the buffer vessel.

14. The facility of claim 7, further comprising:
a pressure measuring member that measures a pressure inside the buffer vessel;
a lower sensor detecting a height of the liquid chemical present in the buffer vessel for determining a time to start supplying a liquid chemical from the liquid storage container to the buffer vessel;
valves installed at the chemical inlet pipe, the chemical supply pipe, the gas inlet pipe, and the vent line, respectively; and
a controller receiving sensing signals from the lower sensor and the pressure measuring member and controlling opening/closing of the valves.

15. A liquid supplying method for supplying liquid from a buffer vessel to a unit external to the buffer vessel by pressurizing the liquid present in the buffer vessel using gas supplied to the buffer vessel, the liquid supplying method comprising:
if the amount of the liquid present in the buffer vessel is reduced to less than a reference level, refilling the buffer vessel by supplying liquid to the buffer vessel; and
if a preset condition is satisfied while repeating the refilling of the buffer vessel, discharging the gas from the buffer vessel through a vent line.

16. The liquid supplying method of claim 15, wherein the preset condition comprises a pressure condition, and the discharging of the gas from the buffer vessel is performed when a pressure inside the buffer vessel is equal to or greater than a reference pressure.

17. The liquid supplying method of claim 15, wherein the discharging of the gas from the buffer vessel is performed using a depressurizing member connected to the vent line.

18. A method for treating substrates, comprising:
performing a predetermined process on substrates in a treatment unit using a vaporized chemical prepared by vaporizing a liquid chemical supplied from a buffer vessel,
supplying the liquid chemical from the buffer vessel to the treatment unit by pressurizing the liquid chemical present in the buffer vessel using gas supplied to the buffer vessel;
if the amount of the liquid chemical present in the buffer vessel reduces to less than a reference level, refilling the buffer vessel by supplying a liquid chemical to the buffer vessel; and
if a preset condition is satisfied while repeating the refilling of the buffer vessel, discharging the gas from the buffer vessel through a vent line.

19. The method of claim 18, wherein the predetermined process is a deposition process for depositing organic metal on the substrates, and the chemical is a precursor of the organic metal.

20. The method of claim 18, wherein after the liquid chemical is stably vaporized, the vaporized chemical is supplied to the treatment unit, and an initial amount of the vaporized chemical that is unstably vaporized is discharged through the pump connected to the vent line.

21. The method of claim 18, wherein the preset condition comprises a pressure condition inside the buffer vessel, and the discharging of the gas from the buffer vessel is performed when a pressure measured inside the buffer vessel is equal to or greater than a first reference pressure.

22. The method of claim 21, wherein the pressure inside the buffer vessel is measured after it is detected that a height of the liquid chemical present in the buffer vessel reaches a first level, and then the discharging of the gas from the buffer vessel is performed according to the measured pressure.

23. The method of claim 22, wherein if the predetermined process continues in the treatment unit when it is detected that the height of the liquid chemical present in the buffer vessel reaches the first level, the discharging of the gas from the buffer vessel is performed according to a pressure inside the buffer vessel measured after the predetermined process is completed.

24. The method of claim 21, wherein the discharging of the gas from the buffer vessel comprises:
opening a valve installed at the vent line for a predetermined time to discharge the gas from the buffer vessel;
measuring a pressure inside the buffer vessel after closing the valve; and
if the measured pressure is greater than a second reference pressure, re-opening the valve for the predetermined time,
wherein the measuring of the pressure and the re-opening of the valve are repeated until the pressure inside the buffer vessel becomes equal to or less than the second reference pressure.

25. The method of claim 18, wherein a valve is installed at a chemical inlet pipe connected between a liquid storage container and the buffer vessel, and when the valve is closed after a liquid chemical is supplied from the liquid storage container to the buffer vessel, a portion of the chemical inlet pipe between the valve and the liquid storage container is filled with the liquid chemical remaining therein.
